(19) United States
(12) Patent Application Publication
(10) Pub. No.: US 2026/0247759 A1
(43) Pub. Date: Aug. 20, 2026

(54) SEMICONDUCTOR STRUCTURE

(71) Applicant: Rayleigh Vision Intelligence Co.,Ltd., Hsinchu City (TW)

(72) Inventor: Jr-Hau He, Hsinchu City (TW)

(21) Appl. No.: 19/171,556

(22) Filed: Apr. 7, 2025

(30) Foreign Application Priority Data
Feb. 20, 2025 (TW) 114106332

(51) Int. Cl. H10H 20/84; H10H 20/01; H10H 20/85

(52) U.S. Cl. CPC H10H 20/84; H10H 20/8508; H10H 20/034

(57) ABSTRACT

A semiconductor structure is revealed, which comprising a light-transmitting substrate, a glue layer disposed on the light-transmitting substrate, and a semiconductor component disposed on the glue layer and comprising a semiconductor unit, an insulating layer covering the semiconductor unit and including a planar portion, and an electrode layer penetrating through the insulating layer and electrically connected to the semiconductor unit, wherein the semiconductor unit, the insulating layer and the electrode layer are disposed on a epitaxial substrate, and then the semiconductor component is transferred to an upper side of the light-transmitting substrate and the glue layer while the insulating layer is adhesive on the glue layer as well as the electrode layer penetrates through the glue layer and electrically connects to the light-transmitting substrate, and the planar portion is formed by etching part of the insulating layer to improve the structural consistency of the semiconductor structure.

### FIELD OF THE INVENTION

The present application relates to a semiconductor structure, and more particularly to a semiconductor structure having a planar portion to improve structural consistency.

### BACKGROUND OF THE INVENTION

In prior art, the external layer of a chip structure is usually covered with an insulating layer to protect the internal structure of the chip structure and ensure its electrical performance and reliability during the manufacturing process and applications. For example, in the Micro LED manufacturing process, the design and formation of the insulating layer will cause many problems, which not only affect the structural integrity of the chip structure, but also have a disadvantageous Influence on a subsequent mass transfer process.

Specifically, during the chip manufacturing process, an insulating layer needs to cover the whole chip structure to achieve the expected insulation effect. However, during the formation of the insulating layer, its peripheral portion often protrudes outward due to process characteristics, forming an additional portion exceeding a main structure of the chip structure. This protruding structure will further form a side skirt-shaped protruding structure on the periphery of the chip structure in a subsequent laser lift-off process. This side skirt-shaped structure is a typical product in existing manufacturing processes and is often produced in Micro LED chip manufacturing technology.

However, the side skirt structure will cause a series of problems in the subsequent mass transfer process. Since the mass transfer process usually involves large-scale transfer operations of chips, such as mechanical bonding, peeling and alignment processes, the side skirt structure is very susceptible to external forces and cracking during these processes. When cracking occurs, it not only damages the external structure of the chip structure, but also causes irreversible dark crack damage to the internal structure of the chip structure. Dark crack damage to the internal structure is usually difficult to be detected in the early stages; however, it may have serious influences on the final performance and the use period of the chip, or even lead to complete destruction of the whole chip structure.

In addition, since the cracking of the side skirt structure may occur at a plurality of stages in the mass transfer process, the cumulative effect of this problem further increases a risk of chip damage. When a plurality of chips are damaged during the same mass transfer process, the whole batch manufacturing yield will drop significantly, resulting in increased manufacturing costs and affecting the market competitiveness of the product.

In summary, in prior art of the chip manufacturing technologies, due to the protruding design of the insulating layer and the side skirt structure formed therein having significant risks of structural cracking and damage, which limit the further development and application of chip manufacturing technology. The industry urgently needs to solve the aforementioned problems.

In light of the above problems of the conventional technology, the present application provides a semiconductor structure, which etches a portion of the insulating layer of the semiconductor component after the semiconductor component is transferred to the substrate, so that the insulating layer on an upper outer edge of the semiconductor component forms a planar portion to improve the structural consistency of the semiconductor structure.

### SUMMARY

An objective of the present application is to provide a semiconductor structure, which is to etch a part of an insulating layer of a semiconductor component after the semiconductor component is transferred to an upper side of a substrate, so that the insulating layer on an upper outer edge of the semiconductor component forms a planar portion, thereby improving the structural consistency of the semiconductor structure, removing the side skirt structure, and avoiding damage to the semiconductor structure.

In order to achieve the above-mentioned objective and effect, the present application provides a semiconductor structure, which includes a light-transmitting substrate, a glue layer and a semiconductor component, the glue layer is disposed on an upper side of the light-transmitting substrate, the semiconductor component is disposed on an upper side of the glue layer, the semiconductor component includes a semiconductor unit, an insulating layer covering an outer side of the semiconductor unit and including a planar portion on an upper outer edge of the semiconductor unit, and an electrode layer penetrating through the insulating layer and electrically connected to and disposed under the semiconductor unit, wherein the semiconductor unit, the insulating layer and the electrode layer are disposed on a epitaxial substrate to form the semiconductor component while the electrode layer penetrates through the insulating layer and is electrically connected to the semiconductor unit. Then the semiconductor component is transferred to the upper sides of the light-transmitting substrate and the glue layer while the insulating layer is adhesive on the glue layer as well as the electrode layer is penetrating through the glue layer and electrically connected to the light-transmitting substrate, and the insulating layer of the semiconductor component forms a protrusion portion at an upper side of the epitaxial substrate, the protrusion portion of the insulating layer is etched to form the planar portion on the upper outer edge of the semiconductor unit; this semiconductor structure improves the structural consistency of the semiconductor structure to avoid damage to the semiconductor structure during transfer.

In an embodiment of the present application, the semiconductor unit is a light emitting diode.

In an embodiment of the present application, the epitaxial substrate is a sapphire substrate.

In an embodiment of the present application, the semiconductor component is separated from the epitaxial substrate by a laser lift-off process.

In an embodiment of the present application, the protrusion portion is further disposed on the upper outer edge of the semiconductor unit while the insulating layer forms the protrusion portion on an upper side of the epitaxial substrate. When the semiconductor component is transferred to the upper side of the light-transmitting substrate and the glue layer, the protrusion portion of the insulating layer is etched so that the insulating layer forms the planar portion on the upper outer edge of the semiconductor unit.

In an embodiment of the present application, the semiconductor component is processed by removing a portion of the insulating layer using an inductively coupled plasma etching or a reactive ion etching to form the planar portion.

In an embodiment of the present application, the planar portion is annularly disposed on the upper outer edge of the semiconductor unit

In an embodiment of the present application, the material of the insulating layer is silicon nitride or silicon oxide.

In an embodiment of the present application, a thickness of the insulating layer is 500 nm~1000 nm, a thickness of the glue layer is 0.1~10 μm, the thickness of the glue layer is corresponding to an area of the semiconductor component, and an absorption wavelength of the glue layer is from 200 nm to 400 nm.

### BRIEF DESCRIPTION OF THE DRAWINGS

FIG. 1 is a schematic diagram of structure according to an embodiment of the present application; and

FIGS. 2A to 2F are schematic diagrams of manufacturing structure according to an embodiment of the present application.

### DETAILED DESCRIPTION

In light of the above-mentioned problems of the conventional technology. The present application etches an insulating layer of a semiconductor component so that the insulating layer forms a planar portion at an upper outer edge of a semiconductor unit of the semiconductor component. The planar portion of the insulating layer is used to improve the structural consistency of the semiconductor structure, thereby solving the problem that the side skirt structure of the conventional technology may damage the chip during mass transfer, resulting in a decrease in yield and an increase in manufacturing cost.

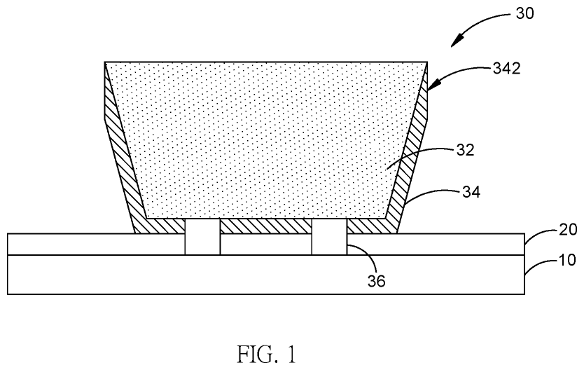

Please refer to FIG. 1, which is a schematic diagram of the structure of an embodiment according to the present application. As shown in the figure, this embodiment is a first embodiment. This embodiment is a semiconductor structure, which includes a light-transmitting substrate 10, a glue layer 20 and a semiconductor component 30.

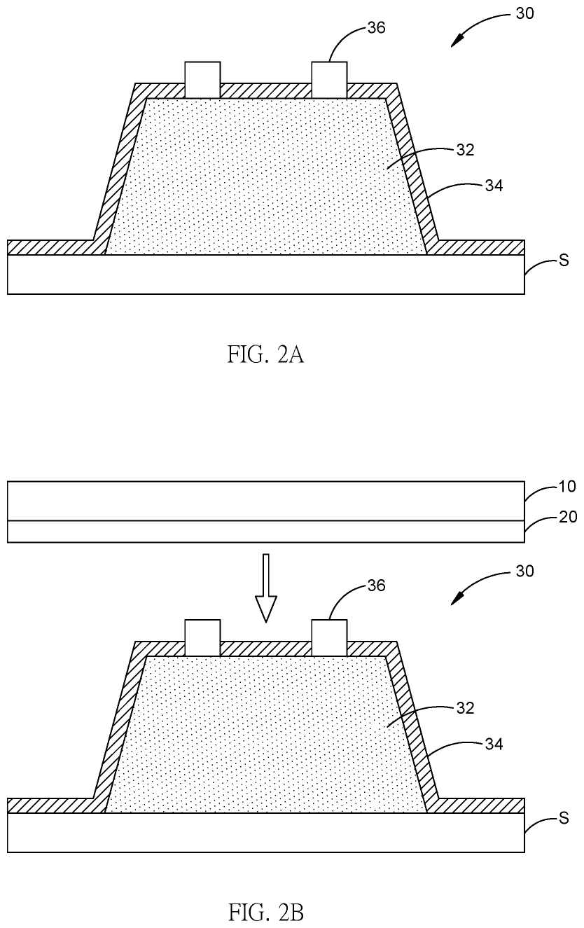

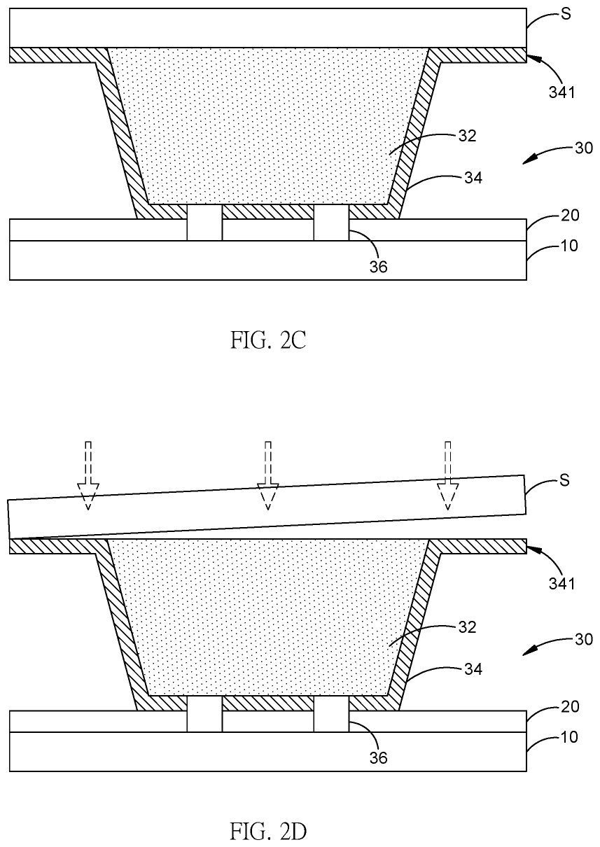

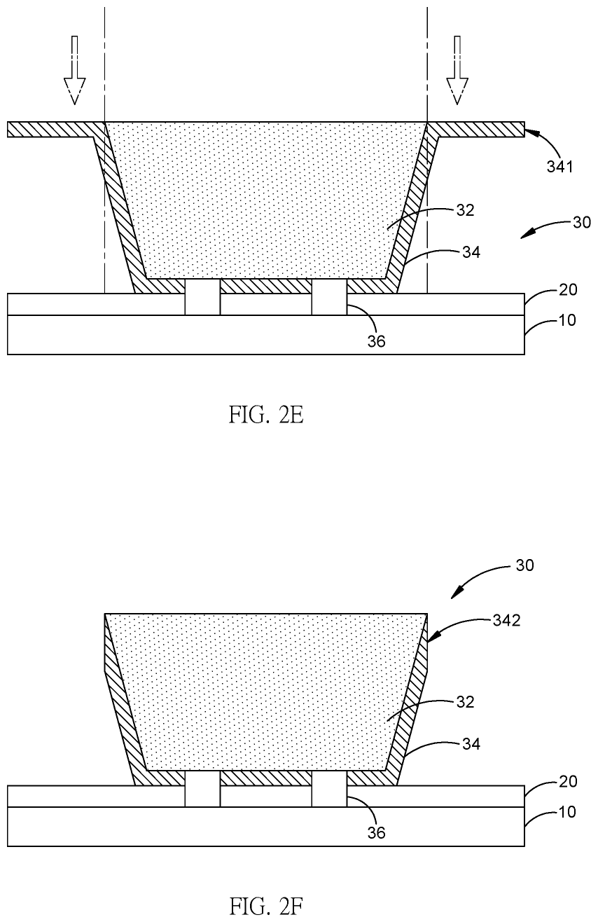

Referring again to FIG. 1 and FIG. 2A to FIG. 2F, FIG. 2A to FIG. 2F are schematic diagrams of manufacturing structure according to an embodiment of the present application. As shown in the figures, in this embodiment, the glue layer 20 is disposed on an upper side of the light-transmitting substrate 10, and the semiconductor component 30 is disposed on an upper side of the glue layer 20. The semiconductor component 30 includes a semiconductor unit 32, an insulating layer 34 and an electrode layer 36, the insulating layer 34 covers an outer side of the semiconductor unit 32, and the insulating layer 34 has a planar portion 342 disposed on an upper outer edge of the semiconductor unit 32, such as a planar surface, the electrode layer 36 penetrates through the insulating layer 34 and is electrically connected and disposed under the semiconductor unit 32, and the electrode layer 36 penetrates through the glue layer 20 and is electrically connected to the light-transmitting substrate 10.

Continuing with the above, as shown in FIG. 2A, when manufacturing the semiconductor component 30, performing epitaxy growing is to grow the semiconductor unit 32, the insulating layer 34 and the electrode layer 36 of the semiconductor component 30 on an epitaxial substrate S, for example, the epitaxial substrate S is a sapphire substrate for growing the semiconductor component 30. That is, the semiconductor component 30 is formed on the epitaxial substrate S. After the semiconductor unit 32 and the electrode layer 36 of the semiconductor component 30 are formed on the epitaxial substrate S while the electrode layer 36 of the semiconductor component 30 is electrically connected to the semiconductor unit 32, an insulating material is required to cover the semiconductor unit 32, namely, the insulating layer 34 covering the semiconductor unit 32, except for areas on the semiconductor unit 32 with the electrode layer 36. The insulating layer 34 is formed evenly on an outside of the semiconductor unit 32 and an exposed surface of the epitaxial substrate S. Afterward, the electrode layer 36 of the semiconductor component 30 is exposed by the insulating layer 34.

Continuing with the above, as shown in FIG. 2B, after the semiconductor component 30 is formed, the light-transmitting substrate 10 and the glue layer 20 are moved toward the semiconductor component 30 to be disposed on an end of the electrode layer 36 of the semiconductor component 30, and then as shown in FIG. 2C, the entire semiconductor structure is flipped over, thereby, the epitaxial substrate S is disposed on the semiconductor component 30 and the semiconductor component 30 is disposed on the light-transmitting substrate 10 and the glue layer 20. At the same time, the insulating layer 34 is adhesive on the glue layer 20 as well as the electrode layer 36 is penetrating through the glue layer 20 and electrically connected to the light-transmitting substrate 10, and then as shown in FIG. 2D, the epitaxial substrate S is removed by a laser lift-off process, as exemplified by the broken line arrows. After the epitaxial substrate S is removed, a portion of the insulating layer 34 originally formed on a surface of the epitaxial substrate S will remain to form a protrusion portion 341, as like the portion of the insulating layer 34 is extended outwardly to form the protrusion portion 341.

Continuing with the above, the protrusion portion 341 is often a side skirt-shaped structure. During the subsequent mass transfer process, the protrusion portion 341 will be cracked due to external force during the mechanical bonding, peeling and alignment process. The cracked protrusion portion 341 will further damage the semiconductor structure and cause dark crack damage to the semiconductor component 30, thereby reducing the performance and life of the semiconductor structure.

Continuing with the above, as shown in FIG. 2E and FIG. 2F, in order to prevent the protrusion portion 341 from damaging in subsequent processes, the protrusion portion 341 of the insulating layer 34 is further etched using inductively coupled plasma (ICP) or reactive ion etching (RIE) to remove the insulating layer 34 at the upper outer edge of the semiconductor unit 32, thereby forming the planar portion 342 annularly disposed on the upper outer edge of the semiconductor unit 32.

In the above embodiments, inductively coupled plasma (ICP) is a plasma generation technology based on electromagnetic induction and is widely used in the fields of chemical analysis, material processing and semiconductor manufacturing. Its principle is based on the alternating magnetic field generated by high-frequency alternating current in the induction coil, which achieves gas ionization and stable maintenance of plasma by inducing electron movement in the gas.

The process of generating inductively coupled plasma begins with the introduction of gas (such as argon). When a high-frequency current passes through the induction coil, an alternating magnetic field is generated, which exerts a force on the free electrons in the gas, causing them to move at high speed. These electrons collide with gas molecules or atoms, triggering a series of ionization processes to form plasma. Due to the continuous action of the induced magnetic field, the electrons in the plasma are continuously accelerated, thus maintaining a high-temperature and stable plasma environment.

The main features of inductively coupled plasma includes an electrodeless design. Traditional plasma generation technology often relies on direct contact with electrodes, but this method may easily cause erosion of the electrode material and lead to impurity contamination. Inductively coupled plasma technology uses an induced magnetic field for energy coupling, avoiding this problem and significantly improving the purity and stability of the plasma. In addition, inductively coupled plasma may generate extremely high plasma temperatures, making it possible to effectively decompose and excite various substances in the sample.

In the above embodiments, reactive ion etching (RIE) is a plasma etching technology widely used in semiconductor manufacturing and micro-nano processing. It combines chemical reaction and physical etching mechanisms to achieve precise selective removal of material surfaces. Reactive ion etching technology has become a key step in manufacturing fine structures in modern semiconductor processes due to its high directionality, high resolution and excellent material compatibility.

The process principle of reactive ion etching is based on the generation and control of plasma. In a reactive ion etching system, a specific gas (such as fluoride or chloride gas) is injected into a reaction chamber, and a high-frequency electric field is applied to the gas through a radio frequency power supply to excite and generate plasma. The ions and free radicals in the plasma will react chemically with the surface of the material to generate volatile by-products, which are then pumped away by the vacuum pump, thereby removing the material. In addition, the ions driven by the electric field will Influence the surface of the material in a highly directional manner, achieving physical etching and further enhancing the vertical directionality of the etching.

The combination of chemical reaction and physical etching is the core characteristic of reactive ion etching. Chemical reactions provide high selectivity and may effectively distinguish etching targets from mask materials based on material properties and the choice of reactive gases; physical etching brings excellent directionality and is suitable for manufacturing deep and narrow structural features, such as transistor trenches, microelectromechanical systems (MEMS) structures, and fine patterns in optical devices.

Reactive ion etching technology has flexible process adjustability. By adjusting gas composition, gas pressure, RF power and electrode bias, the reactive ion etching system may precisely control the etching rate, selectivity and directionality. Different gases produce different reactive ions and are suitable for processing different materials. For example, fluorine-based gases are often used for etching silicon, while chlorine-based gases are suitable for etching metals and compound semiconductors.

In the above embodiments, a light-emitting device is taken as an example of the semiconductor device, the semiconductor component 30 may be a light-emitting element, and the semiconductor unit 32 may be a light-emitting unit, such as a light-emitting diode.

In the above embodiments, a thickness of the glue layer 20 is 0.1~10 μm, the thickness of the glue layer 20 corresponding to the area of the semiconductor component 30 with better Lift-off effect as shown in following table.

TABLE the relationship between the thickness of the glue
layer 20 and the area of the semiconductor component 30

| | area of |
|---|---|
| thickness of | semiconductor |
| glue layer (μm) | component (μm²) |
| 1~5 | <100 |
| 0.5~4 | 100~799 |
| 0.1~3 | 800~2000 |

This application is to provide the semiconductor structure with a respective thickness of the glue layer 20 corresponding to a respective area of the semiconductor component 30 for reducing the semiconductor component 30 in damage and offset flipping.

An absorption wavelength band of the glue layer 20 is from 200 nm to 400 nm, for example, a material of the glue layer 20 is selected from a Laser Lift-off material or a Laser Debonding material, which commonly is a polyimide material or silicon oxide material, which is usually used to absorb the energy of the laser in 355 nm, even to absorb the energy of the laser in 248 nm or 266 nm.

In summary, the present application provides a semiconductor structure, which is a structure in which the protrusion portion of the insulating layer outside the semiconductor component is etched after the semiconductor component is transferred from the epitaxial substrate to the light-transmitting substrate, so that the insulating layer forms a planar portion annularly disposed on the outer edge of the semiconductor component. The planar portion may make the semiconductor structure be in structure consistent, and solve the problem of the side skirt structure produced by the insulating layer in the conventional technology, which is damaged in the subsequent process, resulting in a decrease in yield and an increase in manufacturing cost.

Therefore, the present application is undoubtedly novel, progressive, and applicable to the industry. Therefore, a patent application is submitted in accordance with that the patent will be granted as soon as possible.

The above description is only an embodiment of the present application and is not intended to limit the scope of the present application. Therefore, any equivalent changes and modifications made in accordance with the shape, structure, features, and spirit described in the patent application scope of the present application shall be included in the patent application scope of the present application.

What is claimed is:

1. A semiconductor structure, comprising:
a light-transmitting substrate;
a glue layer, disposed on the light-transmitting substrate; and
a semiconductor component, disposed on the glue layer, the semiconductor component comprising:
a semiconductor unit;
an insulating layer, covering an outer side of the semiconductor unit, and the insulating layer including a planar portion on an upper outer edge of the semiconductor unit; and
an electrode layer, penetrating through the insulating layer and electrically connected to and disposed under the semiconductor unit;
wherein the semiconductor unit, the insulating layer and the electrode layer are disposed on a epitaxial substrate to form the semiconductor component while the electrode layer penetrates through the insulating layer and is electrically connected to and disposed under the semiconductor unit, then the semiconductor component is transferred to the upper side of the light-transmitting substrate and the glue layer while the insulating layer is adhesive on the glue layer as well as the electrode layer is penetrating through the glue layer and electrically connected to the light-transmitting substrate, and a protrusion portion of the insulating layer is etched to form the planar portion on an upper outer edge of the semiconductor unit.

2. The semiconductor structure of claim 1, wherein the semiconductor unit is a light-emitting diode.

3. The semiconductor structure of claim 1, wherein the epitaxial substrate is a sapphire substrate.

4. The semiconductor structure of claim 1, wherein the semiconductor component is separated from the epitaxial substrate by a laser lift-off process.

5. The semiconductor structure of claim 1, wherein the insulating layer forms the protrusion portion on the epitaxial substrate, and the protrusion portion is further disposed on the upper outer edge of the semiconductor unit, and when transferred to the upper side of the light-transmitting substrate and the glue layer, the protrusion portion is etched to form the planar portion on the upper outer edge of the semiconductor unit.

6. The semiconductor structure of claim 1, wherein the semiconductor component removes the protrusion portion of the insulating layer by an inductively coupled plasma etching or a reactive ion etching to form the planar portion.

7. The semiconductor structure of claim 1, wherein the planar portion is annularly disposed on the upper outer edge of the semiconductor unit.

8. The semiconductor structure of claim 1, wherein a material of the insulating layer is silicon nitride or silicon oxide.

9. The semiconductor structure of claim 1, wherein a thickness of the insulating layer is 500 nm to 1000 nm.

10. The semiconductor structure of claim 1, wherein a thickness of the glue layer is 0.1 μm~10 μm, and the thickness of the glue layer is corresponding to an area of the semiconductor component.

11. The semiconductor structure of claim 1, wherein an absorption wavelength band of the glue layer is from 200 nm to 400 nm.
